(19) United States
(12) Patent Application Publication
(10) Pub. No.: US 2026/0007063 A1
(43) Pub. Date: Jan. 1, 2026

(54) METHOD FOR MANUFACTURING SEMICONDUCTOR DEVICE

(71) Applicant: Japan Display Inc., Tokyo (JP)

(72) Inventors: Akihiro HANADA, Tokyo (JP); Motochika YUKAWA, Tokyo (JP); Takuo KAITOH, Tokyo (JP)

(73) Assignee: Japan Display Inc., Tokyo (JP)

(21) Appl. No.: 19/241,397

(22) Filed: Jun. 18, 2025

(30) Foreign Application Priority Data
Jun. 27, 2024 (JP) 2024-104324
May 12, 2025 (JP) 2025-079547

(51) Int. Cl. H10K 71/00; H10K 39/32

(52) U.S. Cl. CPC H10K 71/621; H10K 39/32

(57) ABSTRACT

A method for manufacturing a semiconductor device for radiation detection device according to an embodiment of the present invention includes: forming a first gate electrode above an insulating surface; forming a first nitride insulating layer above the first gate electrode; forming a first oxide insulating layer above the first nitride insulating layer, a thickness of the first oxide insulating layer being 20 nm or less; forming an oxide semiconductor layer above the first oxide insulating layer; forming a transparent conductive layer above the oxide semiconductor layer; and forming a source electrode and a drain electrode by etching the transparent conductive layer using the first oxide insulating layer and the oxide semiconductor layer as etching stoppers.

### CROSS-REFERENCE TO RELATED APPLICATIONS

This application claims the benefit of priority to Japanese Patent Application No. 2024-104324, filed on Jun. 27, 2024 and Japanese Patent Application No. 2025-079547, filed on May 12, 2025, the entire contents of each are incorporated herein by reference.

### FIELD

An embodiment of the present invention relates to a semiconductor device and a radiation detector. In particular, an embodiment of the present invention relates to a radiation detector including a semiconductor device in which an oxide semiconductor is used as a channel.

### BACKGROUND

In recent years, instead of amorphous silicon, low-temperature polysilicon, and single crystal silicon, development of a semiconductor device in which an oxide semiconductor is used as a channel has been advanced (for example, Japanese Laid-Open Patent Publication No. 2021-141338). The semiconductor device in which the oxide semiconductor is used as the channel can be formed by a simple structure and a low-temperature process similar to a semiconductor device in which amorphous silicon is used as a channel. It is known that the semiconductor device in which the oxide semiconductor is used as the channel has higher mobility than the semiconductor device in which the amorphous silicon is used as the channel.

In order for the semiconductor device in which the oxide semiconductor is used as the channel to operate stably, it is important to reduce oxygen vacancies formed in an oxide semiconductor layer by supplying oxygen to the oxide semiconductor layer in a manufacturing process of the semiconductor device. For example, a technique of forming an insulating layer covering the oxide semiconductor layer under a condition that the insulating layer contains more oxygen is disclosed as a method of supplying oxygen to the oxide semiconductor layer.

### SUMMARY

A method for manufacturing a semiconductor device for a radiation detection device according to an embodiment of the present invention includes: forming a first gate electrode above an insulating surface; forming a first nitride insulating layer above the first gate electrode; forming a first oxide insulating layer above the first nitride insulating layer, a thickness of the first oxide insulating layer being 20 nm or less; forming an oxide semiconductor layer above the first oxide insulating layer; forming a transparent conductive layer above the oxide semiconductor layer; and forming a source electrode and a drain electrode by etching the transparent conductive layer using the first oxide insulating layer and the oxide semiconductor layer as etching stoppers.

A method for manufacturing a semiconductor device according to an embodiment of the present invention includes: forming a first gate electrode above an insulating surface; forming a first nitride insulating layer above the first gate electrode; forming a first oxide insulating layer above the first nitride insulating layer, a thickness of the first oxide insulating layer being 20 nm or less; forming an oxide semiconductor layer above the first oxide insulating layer; forming a transparent conductive layer above the first oxide insulating layer and the oxide semiconductor layer; and forming a source electrode and a drain electrode by etching the transparent conductive layer so that the oxide semiconductor layer remains above the first oxide insulating layer in a channel region and so that the first oxide insulating layer remains above the first nitride insulating layer in a region in which the transparent conductive layer is removed and other than the channel region in a plan view.

A method for manufacturing a semiconductor device according to an embodiment of the present invention includes: forming a first gate electrode above an insulating surface; forming a first nitride insulating layer above the first gate electrode; forming a first oxide insulating layer above the first nitride insulating layer, a thickness of the first oxide insulating layer being 20 nm or less; forming a transparent conductive layer above the first oxide insulating layer; forming a source electrode and a drain electrode by etching the transparent conductive layer using the first oxide insulating layer as an etching stopper; and forming an oxide semiconductor layer above each of the source electrode, the drain electrode and the first oxide insulating layer between the source electrode and the drain electrode.

A method for manufacturing semiconductor device according to an embodiment of the present invention includes: forming a first gate electrode above an insulating surface; forming a first nitride insulating layer above the first gate electrode; forming a first oxide insulating layer above the first nitride insulating layer, a thickness of the first oxide insulating layer being 20 nm or less; forming a transparent conductive layer above the first oxide insulating layer; forming a source electrode and a drain electrode by etching the transparent conductive layer so that the first oxide insulating layer remains above the first nitride insulating layer in a region where the transparent conductive layer is removed; and forming an oxide semiconductor layer above each of the source electrode, the drain electrode and the first oxide insulating layer between the source electrode and the drain electrode.

### BRIEF DESCRIPTION OF DRAWINGS

FIG. 1 is a cross-sectional view showing an overview of a radiation detection device according to an embodiment of the present invention.

FIG. 2 is a circuit diagram showing an overview of a radiation detection device according to an embodiment of the present invention.

FIG. 3 is a cross-sectional view of a semiconductor device according to an embodiment of the present invention.

FIG. 4 is a flowchart showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view of a semiconductor device according to an embodiment of the present invention.

FIG. 12 is a flowchart showing a method for manufacturing a semiconductor device according to an embodiment of the present invention.

FIG. 13 is a cross-sectional view showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a cross-sectional view showing a method for manufacturing a semiconductor device according to an embodiment of the present invention.

FIG. 19 is a cross-sectional view of a semiconductor device according to an embodiment of the present invention.

FIG. 20 is a flowchart showing a method for manufacturing a semiconductor device according to an embodiment of the present invention.

FIG. 21 is a cross-sectional view showing a method for manufacturing a semiconductor device according to an embodiment of the present invention.

FIG. 22 is a cross-sectional view showing a method for manufacturing a semiconductor device according to an embodiment of the present invention.

FIG. 23 is a cross-sectional view showing a method for manufacturing a semiconductor device according to an embodiment of the present invention.

FIG. 24 is a cross-sectional view showing a method for manufacturing a semiconductor device according to an embodiment of the present invention.

FIG. 25 is a cross-sectional view showing a method for manufacturing a semiconductor device according to an embodiment of the present invention.

FIG. 26 is a cross-sectional view showing a method for manufacturing a semiconductor device according to an embodiment of the present invention.

### DESCRIPTION OF EMBODIMENTS

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, thicknesses, shapes, and the like of respective portions as compared with actual embodiments. However, the shown shapes are merely examples, and do not limit the interpretation of the present invention. In the present specification and the drawings, the same reference signs are given to the same components as those described above with respect to the drawings already described and detailed description thereof may be omitted as appropriate.

In each embodiment of the present invention, a direction from a substrate toward an oxide semiconductor layer is referred to as “upper” or “above.” Conversely, a direction from the oxide semiconductor layer toward the substrate is referred to as “lower” or “below.” As described above, for convenience of explanation, although the term “above” or “below” will be used for explanation, for example, the vertical relationship between the substrate and the oxide semiconductor layer may be different from that shown in the diagrams. In the following description, for example, the expression “oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which a plurality of layers is stacked, and in the case where a first member is expressed as a first member above the transistor, the transistor and the first member may have a positional relationship in which the transistor and the first member do not overlap in a plan view. On the other hand, the expression “first member vertically above the transistor” means a positional relationship in which the transistor and the first member overlap in a plan view.

As used herein, the phrases “α includes A, B, or C,” “a includes any of A, B, or C,” “α includes one selected from a group consisting of A, B, and C,” and the like do not exclude the case where α includes a plurality of combinations of A to C unless otherwise indicated. Furthermore, these expressions do not exclude the case where a includes other elements.

In addition, the following embodiments can be combined with each other as long as there is no technical contradiction.

An insulating layer formed under a condition of containing more oxygen contains many defects. Due to this effect, a characteristic variation of the semiconductor device in a reliability test occurs. The characteristic variation in the reliability test is considered to be caused by the trapping of holes in the defects in the insulating layer. In the case where a semiconductor device in which a hole trap is formed is used in a detector for radiation, a characteristic variation of the semiconductor device occurs due to trapping of a hole generated by irradiation of the radiation. It is required to suppress such characteristic variation.

An object of an embodiment of the present invention is to realize a highly reliable semiconductor device for a radiation detector.

### 1. First Embodiment

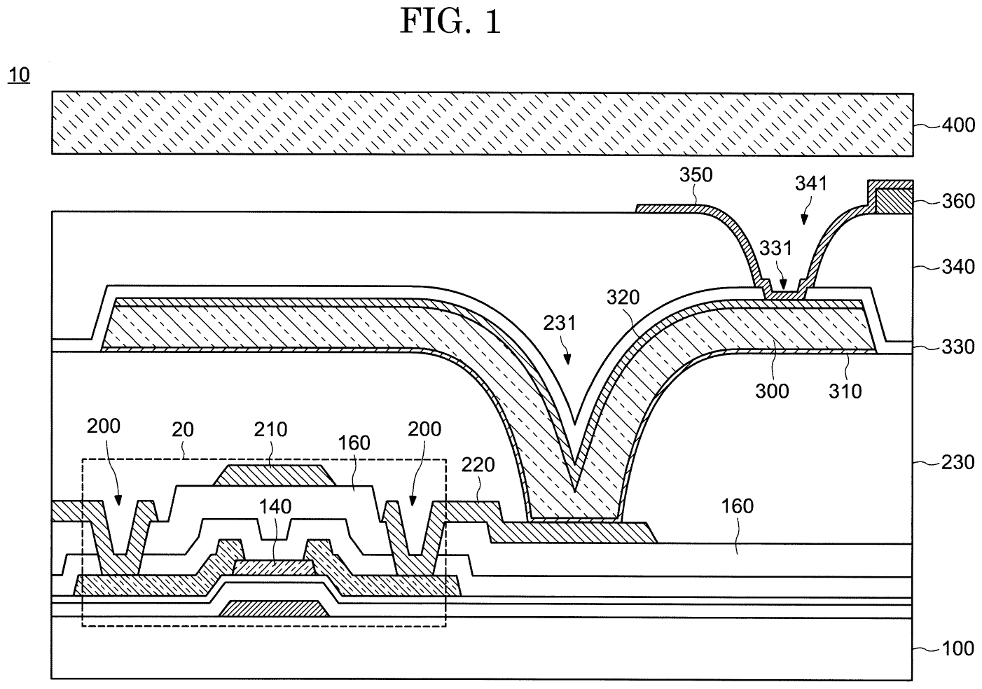

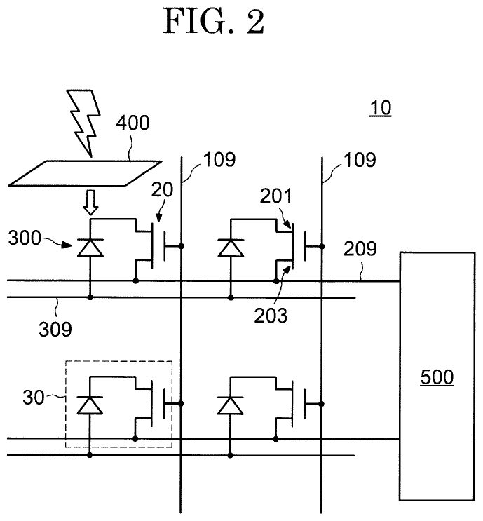

A configuration of a radiation detector 10 according to an embodiment of the present invention will be described with reference to FIG. 1 and FIG. 2. FIG. 1 is a cross-sectional view showing an outline of a radiation detector according to an embodiment of the present invention. FIG. 2 is a circuit diagram showing an outline of a radiation detector according to an embodiment of the present invention.

### [1-1. Configuration of Radiation Detector 10]

As shown in FIG. 1, the radiation detector 10 is arranged on a substrate 100. The radiation detector 10 includes a semiconductor device 20, a photoelectric conversion layer 300, and a wavelength conversion layer 400. The radiation detector 10 includes, in addition to the members described above, a gate electrode 210, a connection wiring 220, an insulating layer 230, a lower electrode 310, an upper electrode 320, insulating layers 330 and 340, and wirings 350 and 360. A detailed structure of the semiconductor device 20 will be described later.

The top layer of the semiconductor device 20 is a wiring 200 and the gate electrode 210. The wiring 200 and the gate electrode 210 are arranged on the insulating layer 160. The gate electrode 210 functions as a light shielding layer and is arranged in a region overlapping an oxide semiconductor layer 140 constituting a channel of the semiconductor device 20 in a plan view. In a top view, the gate electrode 210 is arranged so as to cover at least the oxide semiconductor layer 140 in a channel region. The connection wiring 220 is arranged on the insulating layer 160 and is connected to the semiconductor device 20. Although details will be described later, the connection wiring 220 is connected to a source wiring 201 of the semiconductor device 20.

The insulating layer 230 is arranged on the insulating layer 160, the wiring 200, the gate electrode 210, and the connection wiring 220. The insulating layer 230 covers a pattern end of the wiring 200, a pattern end of the gate electrode 210 and a pattern end of the connection wiring 220. The insulating layer 230 releases a step formed by the semiconductor device 20, the gate electrode 210, and the connection wiring 220. The insulating layer 230 may be referred to as a planarization layer. An organic insulating layer is used as the insulating layer 230. An opening 231 is arranged in the insulating layer 230. The opening 231 reaches the connection wiring 220.

The lower electrode 310 is arranged on the insulating layer 230 and inside the opening 231. The lower electrode 310 is in contact with the connection wiring 220 at the bottom of the opening 231. The photoelectric conversion layer 300 and the upper electrode 320 are arranged on the lower electrode 310. That is, the photoelectric conversion layer 300 is connected to the semiconductor device 20 via the lower electrode 310 and the connection wiring 220. The photoelectric conversion layer 300 includes an N-type semiconductor layer, a P-type semiconductor layer, and an intrinsic semiconductor layer. The intrinsic semiconductor layer is arranged between the N-type semiconductor layer and the P-type semiconductor layer. One of the N-type semiconductor layer and the P-type semiconductor layer is in contact with the lower electrode 310, and the other is in contact with the upper electrode 320.

The photoelectric conversion layer 300 has a function of converting light energy into electrical energy. When the light energy is absorbed by the intrinsic semiconductor layer of the photoelectric conversion layer 300, the semiconductor is photoexcited to generate a pair of electrons and holes. The generated electrons and holes flow through the N-type semiconductor layer and the P-type semiconductor layer to the lower electrode 310 and the upper electrode 320. The intensity of the light irradiated to the photoelectric conversion layer 300 can be detected by detecting a current generated by the electrons and the holes generated by the photoexcitation.

The insulating layer 330 is arranged on the upper electrode 320. An opening 331 is arranged on the insulating layer 330. The opening 331 reaches the upper electrode 320. The insulating layer 340 is arranged on the insulating layer 330. An opening 341 is arranged on the insulating layer 340. In a plan view, the opening 341 is larger than the opening 331. The opening 341 reaches portions of the upper electrode 320 and the insulating layer 330. An inorganic insulating layer is used as the insulating layer 330. An organic insulating layer is used as the insulating layer 340. The insulating layer 330 has a shape reflecting steps formed by the lower electrode 310, the photoelectric conversion layer 300, and the upper electrode 320. On the other hand, the insulating layer 340 releases the steps. That is, the insulating layer 340 is a planarization layer.

The wiring 360 is arranged on the insulating layer 340 and in a region not overlapping the photoelectric conversion layer 300 in a plan view. The wiring 350 is arranged on the insulating layer 340, on the wiring 360, and inside the opening 341. The wiring 350 is in contact with the upper electrode 320 at the bottom of the opening 341.

Although details will be described later, a transparent conductive layer is used as the upper electrode 320 and the wiring 350 in order for visible light emitted from the wavelength conversion layer 400 to efficiently reach the photoelectric conversion layer 300. On the other hand, the wiring 360 is an opaque metal layer. The electrical resistance of the metal layer used as the wiring 360 is lower than the electrical resistance of the transparent conductive layer used as the wiring 350. However, a transparent conductive layer may be used as the wiring 360.

The wavelength conversion layer 400 is arranged above the wiring 350 so as to face the photoelectric conversion layer 300. The wavelength conversion layer 400 may be bonded to the wiring 350 and the insulating layer 340 by an adhesive layer, or a positional relationship between the wiring 350 and the insulating layer 340 may be fixed by a different fixing member. The wavelength conversion layer 400 has a function of converting radiation into visible light. For example, the wavelength conversion layer 400 includes a phosphor that absorbs X-rays, α-rays, or γ-rays and emits visible light. The wavelength conversion layer 400 may be referred to as a scintillator.

When radiation enters the wavelength conversion layer 400 from above, the radiation is converted into visible light by the wavelength conversion layer 400. When the converted visible light enters the photoelectric conversion layer 300, light energy is converted into electric energy, and the converted electric energy is detected as a current. Since there is a correlation between the intensity of the radiation incident on the wavelength conversion layer 400 and the detected current, the intensity of the radiation can be evaluated from a magnitude of the current.

As shown in FIG. 2, pixels 30 are arranged in a matrix in the radiation detector 10. The pixel 30 includes the semiconductor device 20 and the photoelectric conversion layer 300. A gate electrode of the semiconductor device 20 is connected to a gate control line 109. The source wiring 201 of the semiconductor device 20 is connected to a cathode of the photoelectric conversion layer 300. An anode of the photoelectric conversion layer 300 is connected to a wiring 309. A drain wiring 203 of the semiconductor device 20 is connected to a wiring 209. The wiring 209 is connected to a charge amplifier circuit 500.

As described above, the radiation incident on the wavelength conversion layer 400 is converted into visible light, and the visible light is converted into electric energy by the photoelectric conversion layer 300. In this case, by supplying a bias voltage to the wiring 309 connected to the pixel 30 for detecting radiation and supplying a signal for controlling the semiconductor device 20 to be in an ON state to the gate control line 109 connected to the pixel 30, the electric energy is detected as a current flowing through the semiconductor device 20. The current flowing through the semiconductor device 20 is supplied to the charge amplifier circuit 500 via the wiring 209. Then, the charge amplifier circuit 500 converts a charge signal into a voltage signal, and outputs the voltage signal to the outside. It is possible to evaluate the intensity of the radiation irradiated to the pixel 30 by the above operation.

As shown in FIG. 1, ideally, all of the radiation incidents from above are absorbed by the wavelength conversion layer 400, but in practice, part of the radiation is transmitted through the wavelength conversion layer 400. Furthermore, ideally, the radiation transmitted through the wavelength conversion layer 400 is blocked by the gate electrode 210, but in practice, the radiation passes around the gate electrode 210 due to reflection by another member or the like, and reaches the oxide semiconductor layer 140. When radiation enters the oxide semiconductor layer 140, a pair of electrons and holes are generated in the oxide semiconductor layer 140. In the case where a hole trap is formed in the oxide insulating layer adjacent to the oxide semiconductor layer 140, the generated hole is trapped in the oxide insulating layer. This may cause a problem in that the electrical characteristics of the semiconductor device 20 shift in a negative direction.

### [1-2. Configuration of Semiconductor Device 20]

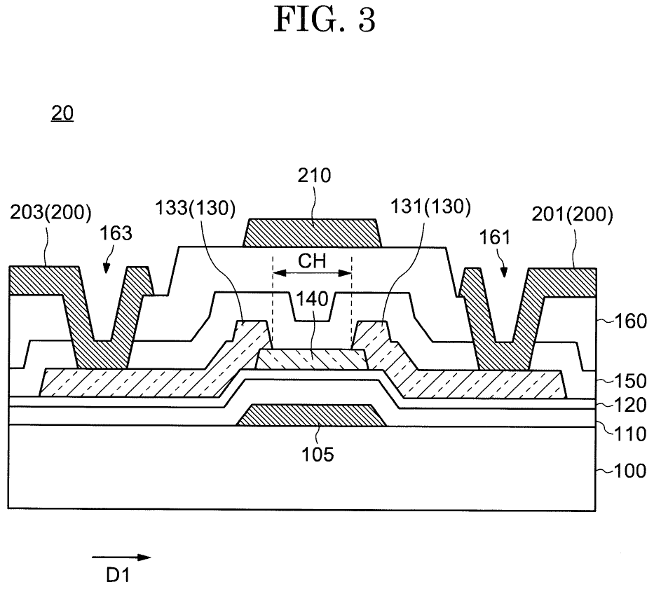

A configuration of the semiconductor device 20 included in the radiation detector 10 according to an embodiment of the present invention will be described with reference to FIG. 3. FIG. 3 is a cross-sectional view of a semiconductor device according to an embodiment of the present invention.

As shown in FIG. 3, the semiconductor device 20 is arranged on the substrate 100 having an insulating surface. The semiconductor device 20 includes a gate electrode 105, a nitride insulating layer 110, an oxide insulating layer 120, a transparent conductive layer 130, an oxide semiconductor layer 140, an oxide insulating layer 150, a nitride insulating layer 160, a wiring 200, and a gate electrode 210. The semiconductor device 20 is a transistor in which the oxide semiconductor layer 140 is used as a channel.

The transparent conductive layer 130 is referred to as a source electrode 131 or a drain electrode 133 depending on its function. However, depending on the polarity of the transistor, a circuit configuration, and potential of each node, the source electrode and the drain electrode of the transistor may be interchanged. In the case where the source electrode 131 and the drain electrode 133 are not particularly distinguished from each other, they are collectively referred to as the transparent conductive layer 130. The wiring 200 is referred to as a source wiring 201 or a drain wiring 203 depending on its function. The source wiring 201 is connected to the source electrode 131. The drain wiring 203 is connected to the drain electrode 133. In the case where the source wiring 201 and the drain wiring 203 are not particularly distinguished from each other, they are collectively referred to as the wiring 200. The semiconductor device 20 may be a transistor in which a semiconductor other than an oxide semiconductor is used as a channel.

In the present embodiment, a dual-gate transistor in which the gate electrode 105 is arranged below the oxide semiconductor layer 140 and the gate electrode 210 is arranged above the oxide semiconductor layer 140 will be described as the semiconductor device 20. However, the semiconductor device 20 may be a bottom-gate transistor in which only the gate electrode 105 is arranged, or may be a top-gate transistor in which only the gate electrode 210 is arranged.

The gate electrode 105 is arranged on the substrate 100. The gate electrode 105 faces the oxide semiconductor layer 140. A nitride insulating layer 110 and an oxide insulating layer 120 are arranged between the gate electrode 105 and the oxide semiconductor layer 140. In other words, the gate electrode 105 can be said to be arranged between the substrate 100 and the oxide semiconductor layer 140. The nitride insulating layer 110 can be said to be arranged between the gate electrode 105 and the oxide semiconductor layer 140. The oxide insulating layer 120 can be said to be arranged between the nitride insulating layer 110 and the oxide semiconductor layer 140. Although details will be described later, in the present embodiment, the nitride insulating layer 110 contains silicon nitride. The oxide insulating layer 120 includes silicon oxide. The nitride insulating layer 110 and the oxide insulating layer 120 function as gate insulating layers.

The oxide semiconductor layer 140 is arranged on the oxide insulating layer 120. The oxide semiconductor layer 140 is arranged in a region overlapping the gate electrode 105 in a plan view. The transparent conductive layer 130 is arranged on the oxide insulating layer 120 and on the oxide semiconductor layer 140. The source electrode 131 and the drain electrode 133 of the transparent conductive layer 130 both ride on a pattern end portion of the oxide semiconductor layer 140. The source electrode 131 and the drain electrode 133 are separated from each other. A region between the source electrode 131 and the drain electrode 133 is a channel region CH. The source electrode 131 and the drain electrode 133 are both in contact with an upper surface and a side surface of the oxide semiconductor layer 140.

The oxide insulating layer 150 is arranged on the transparent conductive layer 130, on the oxide semiconductor layer 140, and on the oxide insulating layer 120 exposed from the transparent conductive layer 130. The oxide insulating layer 150 is formed from an upper surface of the transparent conductive layer 130 to the upper surface of the oxide semiconductor layer 140 and an upper surface of the oxide insulating layer 120 beyond a pattern end portion of the transparent conductive layer 130. The nitride insulating layer 160 is formed on the oxide insulating layer 150.

Apertures 161 and 163 are arranged in the oxide insulating layer 150 and the nitride insulating layer 160. The apertures 161 and 163 reach the transparent conductive layer 130. The source wiring 201 is arranged on the insulating layer 160 and inside the aperture 161. The drain wiring 203 is arranged on the insulating layer 160 and inside the aperture 163. The source wiring 201 and the drain wiring 203 are connected to the source electrode 131 and the drain electrode 133 at bottom portions of the apertures 161 and 163, respectively. The source wiring 201 is connected to a connection wiring 220 shown in FIG. 1.

A film thickness of the nitride insulating layer 110 is, for example, 50 nm or more and 500 nm or less, 50 nm or more and 400 nm or less, 50 nm or more and 300 nm or less, 50 nm or more and 150 nm or less, or 50 nm or more and 100 nm or less. A film thickness of the oxide insulating layer 120 is, for example, 1 nm or more and 20 nm or less, 3 nm or more and 15 nm or less, or 5 nm or more and 10 nm or less. Since the thickness of the oxide insulating layer 120 falls within the above range, the amount of hole traps formed in an oxide insulating layer adjacent to the oxide semiconductor layer 140 can be reduced, and thus reliability of the semiconductor device 20 with respect to visible light and radiation is improved.

A film thickness of the oxide semiconductor layer 140 is 10 nm or more and 50 nm or less, 10 nm or more and 40 nm or less, or 10 nm or more and 30 nm or less. A film thickness of the oxide insulating layer 150 is, for example, 20 nm or more and 100 nm or less, 30 nm or more and 75 nm or less, or 40 nm or more and 60 nm or less. Since the thickness of the oxide insulating layer 150 falls within the above range, the amount of hole traps formed in the oxide insulating layer adjacent to the oxide semiconductor layer 140 can be reduced, and thus the reliability of the semiconductor device 20 with respect to visible light and radiation is improved.

A film thickness of the nitride insulating layer 160 is, for example, 50 nm or more and 300 nm or less, 50 nm or more and 200 nm or less, or 50 nm or more and 100 nm or less. By setting the thickness of the gate insulating layer 530 within the above range, it is possible to ensure the withstand voltage against the applied voltage required for the gate insulating layer of the semiconductor device 20.

In the present embodiment, a configuration in which the oxide insulating layer 120 and the oxide semiconductor layer 140 are in contact with each other has been exemplified, but the configuration is not limited to this configuration. For example, a metal oxide layer may be arranged between the oxide insulating layer 120 and the oxide semiconductor layer 140. A film thickness of the metal oxide layer is, for example, 1 nm or more and 20 nm or less or 1 nm or more and 10 nm or less. For example, aluminum oxide is used as the metal oxide layer. Aluminum oxide has a high barrier property against gases such as oxygen or hydrogen. The barrier property means a function of suppressing the permeation of a gas such as oxygen or hydrogen through the aluminum oxide. That is, even if a gas such as oxygen or hydrogen is released from a layer arranged below the aluminum oxide film, the gas does not move to a layer arranged above the aluminum oxide film. Alternatively, even if a gas such as oxygen or hydrogen is released from the layer arranged on the aluminum oxide film, the gas does not move to the layer arranged below the aluminum oxide film.

### [1-3. Material of Each Member of Radiation Detector 10]

### [1-3-1. Substrate]

A rigid substrate having translucency, such as a glass substrate, a quartz substrate, or a sapphire substrate, is used as the substrate 100. In the case where the substrate 100 needs to have flexibility, a substrate containing a resin such as a polyimide substrate, an acrylic substrate, a siloxane substrate, or a fluorine resin substrate is used as the substrate 100. In the case where a substrate containing a resin is used as the substrate 100, impurities may be introduced into the resin in order to improve the heat resistance of the substrate 100. A substrate that does not have translucency, such as a silicon substrate, a silicon carbide substrate, a semiconductor substrate such as a compound semiconductor substrate, or a conductive substrate such as a stainless steel substrate, may be used as the substrate 100.

[1-3-2. Conductive Layers such as Electrodes and Wirings]

A general metal material is used as the gate electrodes 105 and 210, the wiring 200, the connection wiring 220, the lower electrode 310, and the wiring 360. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof are used as these members. The materials described above may be used in a single layer or in a stacked layer as these electrodes and wirings. In the case where the gate electrode 210 does not need to be electrically conductive, a black resin may be used as the gate electrode 210.

A transparent conductive layer is used as a transparent conductive layer 130, the upper electrode 320 and the wiring 350. A mixture of indium oxide and tin oxide (ITO) and a mixture of indium oxide and zinc oxide (IZO) may be used as the transparent conductive layer. A material other than the above may be used as the transparent conductive layer.

### [1-3-3. Insulating Layer]

A general insulating material is used as the nitride insulating layers 110 and 160, the oxide insulating layers 120 and 150, and the insulating layers 230, 330 and 340. For example, an inorganic insulating layer containing oxygen such as silicon oxide (SiOₓ), silicon oxynitride (SiOₓN_{y}), aluminum oxide (AlOₓ), or aluminum oxynitride (AlOₓN_{y}) is used as the oxide insulating layers 120 and 510, and the insulating layer 330. An inorganic insulating layer containing nitrogen such as silicon nitride (SiNₓ), silicon nitride oxide (SiNₓO_{y}), aluminum nitride (AlNₓ), or aluminum nitride oxide (AlNₓO_{y}) is used as the nitride insulating layers 110, 160 and 330.

An insulating layer having a function of releasing oxygen by a heat treatment is used as the oxide insulating layer 150. That is, an oxide insulating layer containing excess oxygen is used as the oxide insulating layer 150. For example, the temperature of the heat treatment in which the oxide insulating layer 150 releases oxygen is 600° C. or lower, 500° C. or lower, 450° C. or lower, or 400° C. or lower. That is, for example, the oxide insulating layer 150 releases oxygen at a heat treatment temperature performed in a manufacturing process of the semiconductor device 20 in the case where a glass substrate is used as the substrate 100.

An insulating layer with few defects is used as the oxide insulating layer 120. For example, in the case where a composition ratio of oxygen in the oxide insulating layer 120 is compared with a composition ratio of oxygen in an insulating layer having the same composition as that of the oxide insulating layer 120 (hereinafter referred to as “other insulating layer”), the composition ratio of oxygen in the oxide insulating layer 120 is closer to a stoichiometric ratio with respect to the insulating layer than the composition ratio of oxygen in the other insulating layer. Specifically, in the case where silicon oxide (SiOₓ) is used for each of the oxide insulating layer 120 and the oxide insulating layer 150, the composition ratio of oxygen in the silicon oxide used as the oxide insulating layer 120 is closer to a stoichiometric ratio of silicon oxide than the composition ratio of oxygen in the silicon oxide used as the oxide insulating layer 150. For example, a layer in which no defects are observed when evaluated by electron-spin resonance (ESR) may be used as the oxide insulating layer 120.

SiOₓN_{y} and AlOₓN_{y} are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

An organic insulating layer is used as the insulating layers 230 and 340. For example, polyimide resin, acrylic resin, epoxy resin, silicone resin, fluorine resin, and siloxane resin are used as the organic insulating layer.

### [1-3-4. Oxide Semiconductor Layer]

The oxide semiconductor layer 140 can be formed using a sputtering method. A composition of the oxide semiconductor layer 140 formed by the sputtering method depends on a composition of a sputtering target. In this case, a composition of a metal element of the oxide semiconductor layer 140 can be specified based on a composition of the metal element of the sputtering target.

In the case where the oxide semiconductor layer 140 has the polycrystalline structure, the composition of the oxide semiconductor layer may be specified using an X-ray Diffraction (XRD) method. Specifically, the composition of the metal element of the oxide semiconductor layer can be specified based on the crystal structure and a lattice constant of the oxide semiconductor layer obtained by the XRD method. In addition, the composition of the metal element of the oxide semiconductor layer 140 can be determined using fluorescent X-ray analysis, or Electron Probe Micro Analyzer (EPMA) analysis, or the like. However, the oxygen element contained in the oxide semiconductor layer 140 varies depending on the process conditions of sputtering and the like, so that it may not be specified by these methods.

### [1-3-5. Method for Forming Oxide Semiconductor Layer]

The oxide semiconductor layer can be formed using sputtering and a heat treatment. Here, a method for forming the oxide semiconductor layer will be described.

First, an oxide semiconductor layer is formed by sputtering. The formed oxide semiconductor layer has an amorphous structure. Here, the amorphous structure means a structure in which a long-range ordered structure does not exist and an arrangement of periodic crystal lattices is not observed. For example, in the case where an oxide semiconductor layer having the amorphous structure is observed using an XRD method, a particular peak based on a crystalline structure cannot be obtained in a diffractive pattern. In addition, the oxide semiconductor layer having the amorphous structure may have a short-range ordered structure in a minute region.

The oxide semiconductor layer is formed at a low temperature. For example, a temperature of the substrate on which the oxide semiconductor layer is formed is 150° C. or lower, preferably 100° C. or lower, and more preferably 50° C. or lower. Oxygen partial pressure in a chamber during film formation is 1% or more and 10% or less, preferably 1% or more and 5% or less, and more preferably 2% or more and 4% or less.

Next, a heat treatment is performed on the oxide semiconductor layer formed by sputtering. The heat treatment is performed in the atmosphere, but the atmosphere of the heat treatment is not limited thereto. The temperature of the heat treatment is 300° C. or more and 500° C. or less, preferably 350° C. or more and 450° C. or less. The time of the heat treatment is 15 minutes or more and 120 minutes or less, preferably 30 minutes or more and 60 minutes or less.

### [1-3-6. Method for Manufacturing Semiconductor Device 20]

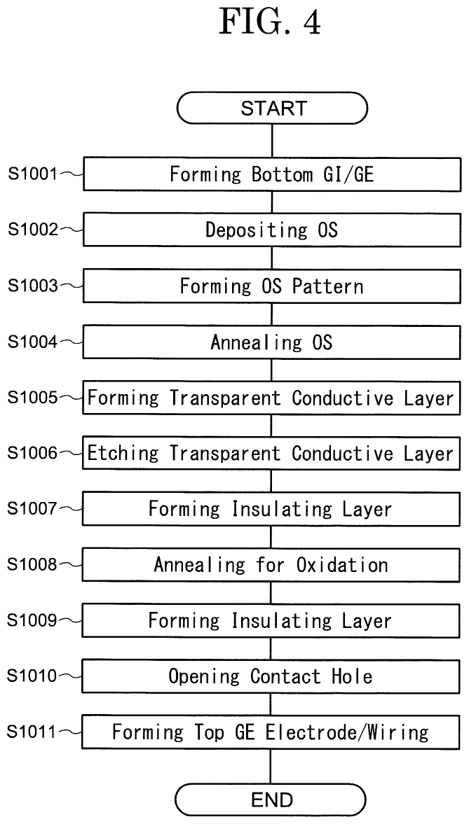

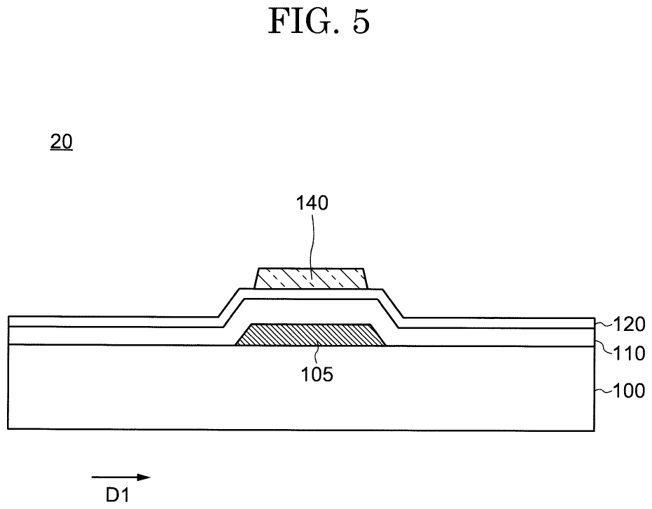

With reference to FIG. 4 to FIG. 10, a method for manufacturing the semiconductor device 20 according to an embodiment of the present invention will be described. FIG. 4 is a flowchart showing a method for manufacturing the semiconductor device 20 according to an embodiment of the present invention. FIG. 5 to FIG. 10 are schematic cross-sectional views showing a method for manufacturing the semiconductor device 20 according to an embodiment of the present invention. Hereinafter, each step of the flowchart shown in FIG. 4 will be described in order.

In step S1001 (Bottom GI/GE formation of FIG. 4), the gate electrode 105 is formed on the insulating surface of the substrate 100, and the nitride insulating layer 110 and the oxide insulating layer 120 are formed on the gate electrode 105 (see FIG. 5). The oxide insulating layer 120 has a film thickness of 20 nm or less. The gate electrode 105 is formed by a PVD (Physical Vapor Deposition) method such as a sputtering method or a vacuum deposition method. The nitride insulating layer 110 and the oxide insulating layer 120 are formed by a CVD (Chemical Vapor Deposition) method or a sputtering method. For example, the nitride insulating layer 110 may block impurities that diffuse from the substrate 100 toward the oxide semiconductor layer 140.

An oxide insulating layer having less defects is used as the oxide insulating layer 120. In order to form an oxide insulating layer having few defects as the oxide insulating layer 120, the oxide insulating layer 120 can be formed at a film forming temperature of 350° C. or higher.

In step S1002 (OS film formation) of FIG. 4, the oxide semiconductor layer 140 is formed on the oxide insulating layer 120 (see FIG. 5). The oxide semiconductor layer 140 is formed by a sputtering method or an atomic layer deposition method (ALD).

For example, in the case where the oxide semiconductor layer 140 is formed by a sputtering method, the oxide semiconductor layer 140 is formed while controlling a temperature of a film-forming target (the substrate 100 and the structure formed thereon).

When film formation is performed on the film-forming target by the sputtering method, ions generated in plasmas and the atoms recoiled by the sputtering target collide with the film-forming target, so that the temperature of the film-forming target increases with the film-forming process. In order to control the temperature of the film-forming target, for example, film formation is performed while cooling the film-forming target.

For example, the film-forming target can be cooled from a surface opposite to the film-forming surface so that the temperature of the film-forming surface of the film-forming target (hereinafter, referred to as “film-forming temperature”) is 100° C. or less, 70° C. or less, 50° C. or less, or 30° C. or less. In particular, the film-forming temperature of the oxide semiconductor layer 140 of the present embodiment is preferably 50° C. or lower. In the present embodiment, the oxide semiconductor layer 140 is formed at a film-forming temperature of 50° C. or lower, and OS annealing, which will be described later, is performed at a heated temperature of 400° C. or higher.

In the sputtering process, the oxide semiconductor layer 140 having an amorphous structure is formed under a condition that the oxygen partial pressure is 10% or less. It is preferable that the oxide semiconductor layer 140 be formed under a condition where the oxygen partial pressure is low. The oxygen partial pressure is, for example, 1% or more and 5% or less, or 2% or more and 4% or less. Under conditions where the oxygen partial pressure is less than 1%, distribution of oxygen in the film forming device tends to be uneven. As a consequence, the composition of oxygen in the oxide semiconductor layer also becomes uneven, and an oxide semiconductor layer containing a large amount of crystal components is formed, or an oxide semiconductor layer which does not crystallize even if an OS annealing process is performed later is formed.

In step S1003 (OS pattern formation) of FIG. 4, a pattern of the oxide semiconducting layer 140 is formed (see FIG. 5). A resist mask (not shown) is formed on the oxide semiconductor layer 140, and the pattern is formed by etching the oxide semiconductor layer 140 using the resist mask. Wet etching may be used as the etching of the oxide semiconductor layer 140, or dry etching may be used. As the wet etching, etching can be performed using an acidic etchant. As the etchant, for example, oxalic acid, PAN, sulfuric acid, hydrogen peroxide solution, or hydrofluoric acid can be used. Through this step, the patterned oxide semiconductor layer 140 can be formed. Thereafter, the resist mask is removed.

Since the oxide semiconductor layer 140 after the OS annealing has a high etching resistance, processing by etching is difficult. Therefore, the formation of the patterned oxide semiconductor layer 140 (that is, the patterning of the oxide semiconductor layer 140) is preferably performed prior to OS annealing.

In step S1004 (OS annealing) in FIG. 4, after the patterned oxide semiconductor layer 140 is formed, a heat treatment (OS annealing) is performed on the oxide semiconductor layer 140. In the OS annealing, the substrate 100 on which the oxide semiconductor layer 140 is formed is held at a predetermined reaching temperature for a predetermined period of time. The predetermined reaching temperature is 300° C. or more and 500° C. or less, or 350° C. or more and 450° C. or less. The holding time at the reached temperature is 15 minutes or more and 120 minutes or less, or 30 minutes or more and 60 minutes or less.

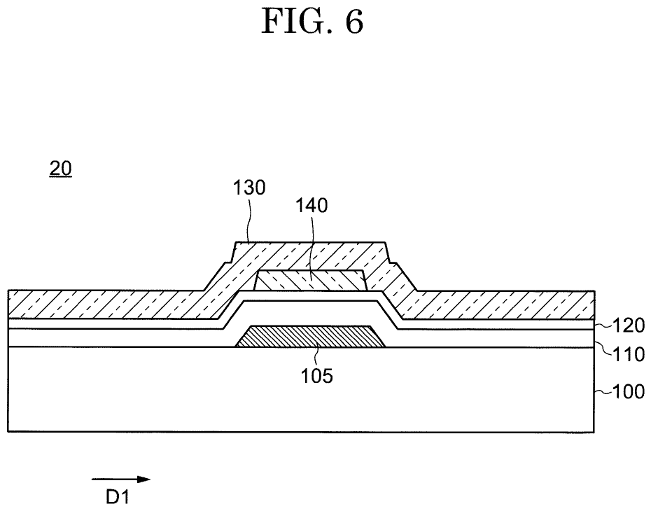

In step S1005 (transparent conductive layer formation) of FIG. 4, a transparent conductive layer 130 is formed on the oxide semiconductive layer 140 and on the oxide insulating layer 120 (see FIG. 6). The transparent conductive layer 130 is formed to cover the oxide semiconductor layer 140 over an end portion of the patterned oxide semiconductor layer 140.

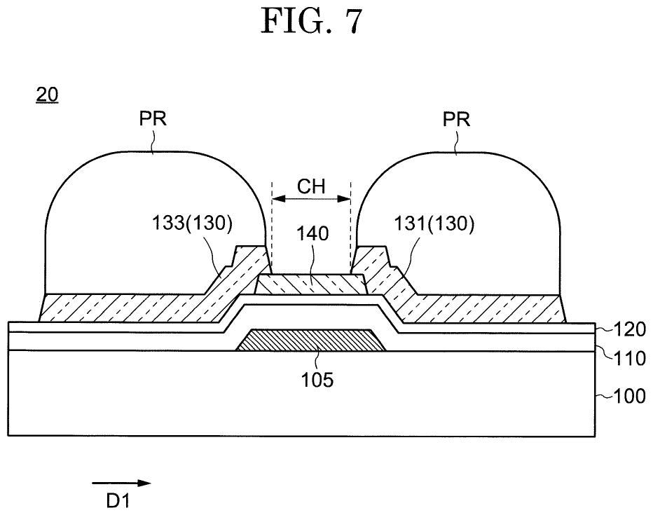

In step S1006 (transparent conductive layer etching) of FIG. 4, a resist mask PR is formed on the transparent conductive layer 130, and the transparent conductive layer 130 is etched using the resist mask PR (see FIG. 7). A pattern of the transparent conductive layer 130 (the source electrode 131 and the drain electrode 133) is formed by the etching process.

As the etching of the transparent conductive layer 130, wet etching may be used, or dry etching may be used. As the wet etching, etching can be performed using an acidic etchant. As the etchant, for example, oxalic acid, PAN, sulfuric acid, hydrogen peroxide solution, or hydrofluoric acid can be used. In the present embodiment, an etchant containing oxalic acid is used.

Here, the oxide insulating layer 120 has etching resistance to the etchant. Similarly, the oxide semiconductor layer 140 has etching resistance to the etchant. In other words, with respect to the etching rate of the etchant, the etching rate of the oxide insulating layer 120 and the oxide semiconductor layer 140 is slower than the etching rate of the transparent conductive layer 130. That is, in the above described etching process, a selection ratio between the transparent conductive layer 130 and the oxide insulating layer 120 and a selection ratio between the transparent conductive layer 130 and the oxide semiconductor layer 140 are both high. Therefore, when the transparent conductive layer 130 is etched, the surfaces of the oxide insulating layer 120 and the oxide semiconductor layer 140 are exposed. That is, in the etching process of the transparent conductive layer 130, the transparent conductive layer 130 is etched using the oxide insulating layer 120 and the oxide semiconductor layer 140 as etching stoppers.

In other words, the above process is that the transparent conductive layer 130 is etched so that the oxide semiconductor layer 140 remains on the oxide insulating layer 120 in the channel region CH in the plan view, and the oxide insulating layer 120 remains on the nitride insulating layer 110 in the region where the transparent conductive layer 130 is removed other than the channel region CH in the plan view. By this step, the patterned transparent conductive layer 130 can be formed without completely removing the oxide insulating layer 120.

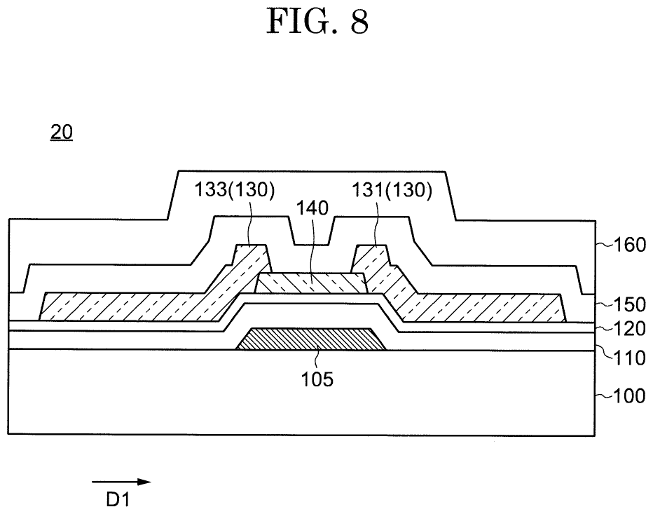

In step S1007 (insulating layer formation) of FIG. 4, an oxide insulating layer 150 is formed on the transparent conductive layer 130, the oxide semiconductor layer 140, and the oxide insulating layer 120 (see FIG. 8). The oxide insulating layer 150 has a thickness of 100 nm or less. The oxide insulating layer 150 is formed by the CVD (Chemical Vapor Deposition) method or a sputtering method.

In order to increase a composition ratio of oxygen in the oxide insulating layer 150, a film may be formed at a relatively low temperature (for example, a film forming temperature of less than 350° C.). Further, after the oxide insulating layer 150 is formed, a process of implanting oxygen into a part of the oxide insulating layer 150 may be performed.

In step S1008 (oxidation annealing) of FIG. 4, a heat treatment is performed while the oxide insulating layer 150 is formed on the oxide semiconductor layer 140. Here, the oxidation annealing may be performed at, for example, 300° C. or higher and 450° C. or lower. Through this step, oxygen released from the oxide insulating layer 150 is supplied to the oxide semiconductor layer 140.

In a process between the formation of the oxide semiconductor layer 140 and the formation of the oxide insulating layer 150 on the oxide semiconductor layer 140, many oxygen defects are generated in the oxide semiconductor layer 140. However, by the oxidation annealing process of step S1008, the oxygen released from the oxide insulating layer 150 is supplied to the oxide semiconducting layer 140, and the oxygen deficiency is repaired.

In step S1009 (insulating layer formation) of FIG. 4, the nitride insulating layer 160 is formed on the oxide insulating layer 150 (see FIG. 8). The nitride insulating layer 160 is formed by the CVD (Chemical Vapor Deposition) method or a sputtering method.

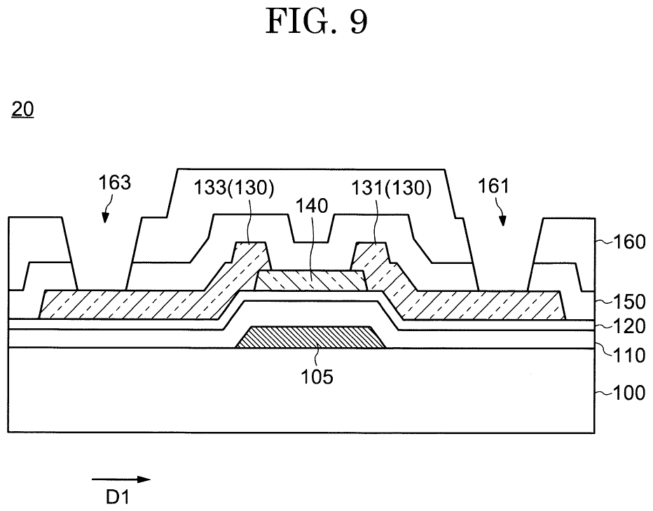

In step S1010 (contact forming) of FIG. 4, the apertures 161 and 163 are formed in the nitride insulating layer 160 and the oxide insulating layer 150 (see FIG. 9). The upper surfaces of the source electrode 131 and the drain electrode 133 are exposed by the aperture formation.

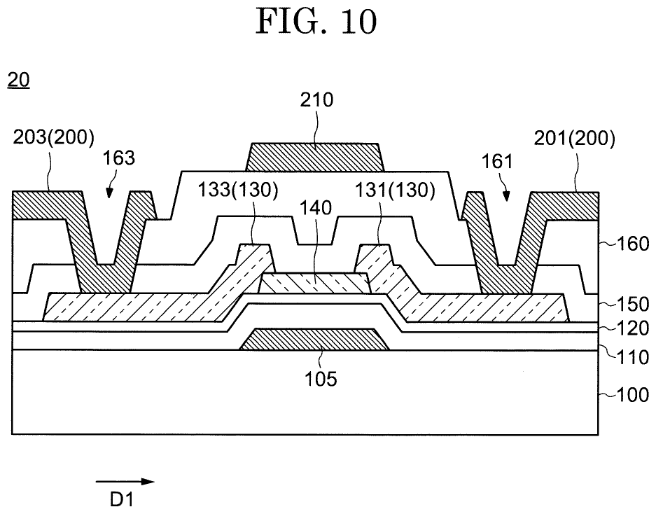

In step S1011 (Top GE electrode/wiring formation) of FIG. 4, the source wiring 201, the drain wiring 203, and the gate electrode 210 are formed (see FIG. 10). The source wiring 201, the drain wiring 203, and the gate electrode 210 are formed by a sputtering method, and are formed by a photolithography process and an etching process. The source wiring 201 and the source electrode 131 are connected at the bottom portion of the aperture 161. The drain wiring 203 and the drain electrode 133 are connected at the bottom portion of the aperture 163. The gate electrode 210 overlaps the oxide semiconductor layer 140 in the channel region CH (the region between the source electrode 131 and the drain electrode 133 in the plan view).

Wet etching may be used, or dry etching may be used as the etching of the source wiring 201, the drain wiring 203, and the gate electrode 210. An aluminum mixed acid solution or a mixed solution of hydrogen peroxide solution and ammonia solution (H₂O₂/NH₃ solution) can be used as the wet etching. A fluorine-containing gas such as sulfur hexafluoride gas (SF₆) or a chlorine-containing gas such as chlorine gas (Cl₂) can be used as the dry etching.

Through the above steps, the semiconductor device 20 shown in FIG. 10 can be manufactured. As shown in FIG. 1, a photoelectric conversion layer 300 connected to the semiconductor device 20 is formed on the semiconductor device 20 formed by the manufacturing method described above, and a wavelength conversion layer 400 is further formed above the photoelectric conversion layer 300 so as to face the photoelectric conversion layer 300.

### [1-3-7. Problems in Conventional Semiconductor Device Manufacturing Method]

In a conventional bottom gate transistor in which an oxide semiconductor layer is used as a channel, instead of the transparent conductive layer 130, a configuration in which a metal layer is used as a source electrode and a drain electrode is mainly used in the present embodiment. In this configuration, as shown in FIG. 7, in a region in which the metal layer is removed except in the channel region CH (a region in which the source electrode and the drain electrode are not formed), the oxide insulating layer 120 below the metal layer is exposed when the metal layer is etched.

In general, dry etching using chlorine gas is adopted as the etching of the metal layer, and it is difficult to ensure a selective ratio between the metal layer and the oxide insulating layer 120 with respect to the dry etching. Therefore, the oxide insulating layer 120 is etched in a region other than a pattern of the metal layer, and the nitride insulating layer 110 below it is exposed. In this process, when the nitride insulating layer 110 is exposed, the threshold voltage is shifted negatively, causing the transistor characteristics to become normally on.

In order to suppress the problem described above, it is necessary to adjust the process so that the nitride insulating layer 110 under the oxide insulating layer 120 is not exposed in the region where the source electrode and the drain electrode are not formed. However, in a radiation detection device as in the present embodiment, a thickness of the oxide insulating layer 120 needs to be 20 nm or less in order to reduce the quantity of hole traps generated by irradiating the oxide insulating layer 120 with radiation.

In the case where the thickness of the oxide insulating layer 120 is 20 nm or less, it is difficult to adjust the region where the source electrode and the drain electrode are not formed so that the nitride insulating layer 110 below the oxide insulating layer 120 is not exposed. Consequently, in the conventional configuration and the conventional manufacturing method, it is not possible to realize a manufacturing method in which the thickness of the oxide insulating layer 120 is 20 nm or less and the nitride insulating layer 110 is not exposed in the region described above.

In a transistor used in devices other than the radiation detection device, even if a problem occurs in which the transistor characteristics become normally on due to exposure of the nitride insulating layer 110, the problem can be solved by simply increasing the thickness of the oxide insulating layer 120. That is, the problem described above is a problem unique to the transistor used in the radiation detection device as in the present embodiment, and is a problem that has not been recognized in the related art. As described above, the problem to be solved by the embodiment according to the present invention is a problem newly recognized in the process leading to the present invention.

As described above, according to the semiconductor device 20 of the present embodiment, in the process of forming the source electrode 131 and the drain electrode 133, even if the thickness of the oxide insulating layer 120 used as the gate insulating layer is 20 nm or less, it is possible to prevent the nitride insulating layer 110 arranged below the oxide insulating layer 120 from being exposed to the surface. As a result, the problem that the transistor characteristics become normally on can be suppressed.

### 2. Second Embodiment

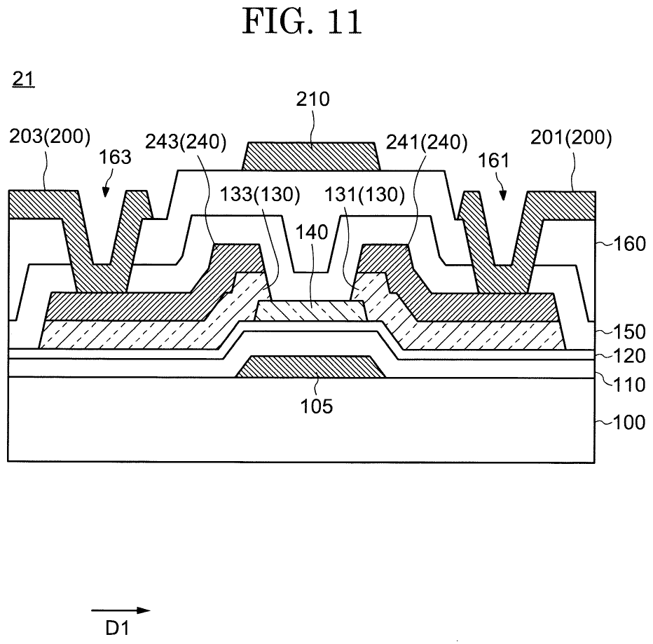

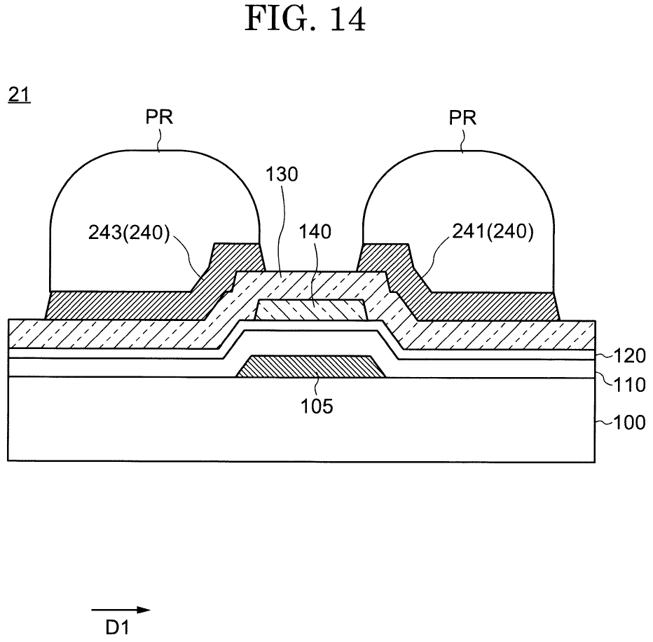

With reference to FIG. 11 to FIG. 18, a configuration of a semiconductor device 21 according to an embodiment of the present invention will be described. The semiconductor device 21 according to the present embodiment is similar to the semiconductor device 20 according to the first embodiment, but is different from the semiconductor device 20 in configurations of a source electrode and a drain electrode.

### [2-1. Configuration of Semiconductor Device 21]

A configuration of the semiconductor device 21 used in a radiation detection device 10 according to an embodiment of the present invention will be described with reference to FIG. 11. FIG. 11 is a cross-sectional view of a semiconductor device according to an embodiment of the present invention. The semiconductor device 21 shown in FIG. 11 is similar to the semiconductor device 20 shown in FIG. 3, but is different from the semiconductor device 20 in that a metal layer 240 is arranged between the transparent conductive layer 130 and the oxide insulating layer 150.

As shown in FIG. 11, the metal layer 240 is arranged on the transparent conductive layer 130. The metal layer 240 is referred to as a source electrode 241 or a drain electrode 243 depending on its function. However, depending on the polarity of the transistor, a circuit configuration, and potential of each node, the source electrode and the drain electrode of the transistor may be interchanged. In the case where the source electrode 241 and the drain electrode 243 are not particularly distinguished from each other, they are collectively referred to as the metal layer 240.

An end portion of the source electrode 131 and an end portion of the source electrode 241 substantially coincide with each other. Similarly, an end portion of the drain electrode 133 and an end portion of the drain electrode 243 substantially coincide with each other. That is, the source electrode 131 and the source electrode 241 have a common planar shape. Similarly, the drain electrode 133 and the drain electrode 243 have a common planar shape.

Here, “common planar shape” means that each layer has substantially the same pattern in a plan view. For example, in the case where etching is performed on a plurality of different layers, a tapered shape may be formed at each pattern end of the plurality of layers by etching. In this case, a pattern of an upper layer is smaller than a pattern of a lower layer, and thus these patterns are not perfectly identical. However, even in such a case, the pattern of the upper layer and the pattern of the lower layer are said to have a common planar shape.

### [2-2. Method for Manufacturing Semiconductor Device 21]

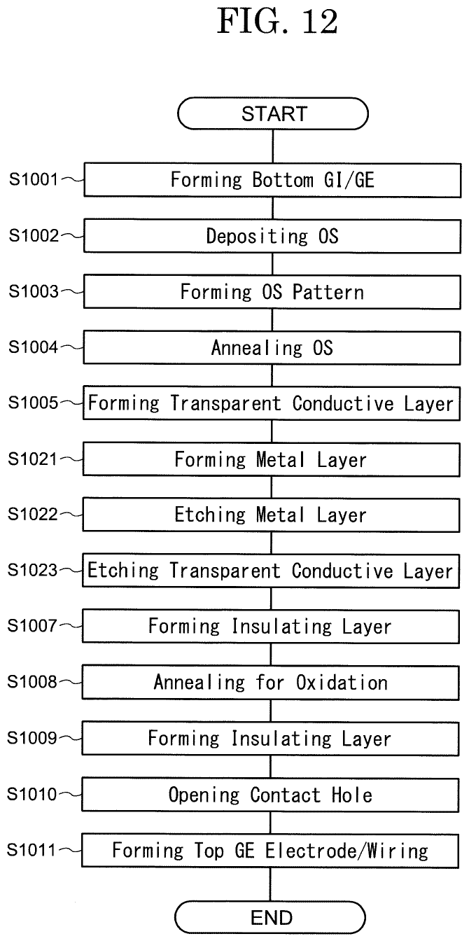

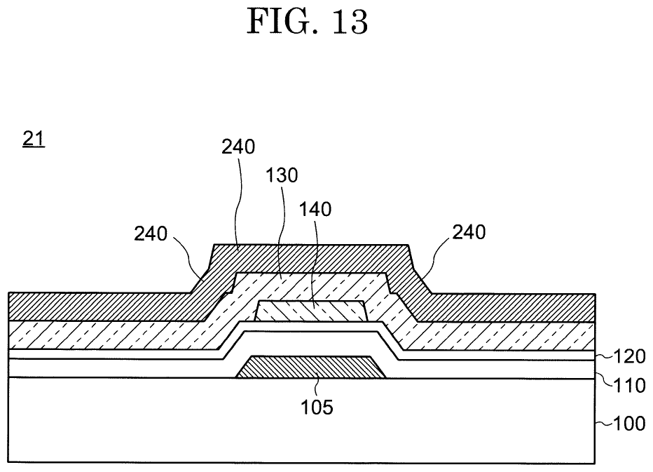

With reference to FIG. 12 to FIG. 18, a method for manufacturing the semiconductor device 21 according to an embodiment of the present invention will be described. FIG. 12 is a flowchart showing a method for manufacturing the semiconductor device 21 according to an embodiment of the present invention. FIG. 13 to FIG. 18 are schematic cross-sectional views showing a method for manufacturing the semiconductor device 21 according to an embodiment of the present invention. The flow chart shown in FIG. 12 is the same as the steps S1001 to S1005 in the flow chart shown in FIG. 4, and therefore the explanation thereof is omitted.

In step S1021 (metal layer formation) of FIG. 12, the metal layer 240 is formed on the transparent conductive layer 130 (see FIG. 13). In step S1022 (metal layer etching) of FIG. 12, the resist mask PR is formed on the metal layer 240, and the metal layer 240 is etched using the resist mask PR. By the etching process, a pattern of the metal layer 240 (the source electrode 241 and the drain electrode 243) is formed.

Dry etching is used as the etching process of the source electrode 241 and the drain electrode 243. As the dry etching, a gas containing chlorine such as chlorine gas (Cl₂) can be used. In the case where the metal layer 240 does not contain aluminum, a fluorine-containing gas such as SF₆ can be used as the dry etching of the metal layer 240.

Here, the transparent conductive layer 130 has etching resistance to the dry etching conditions described above. In other words, an etching rate of the transparent conductive layer 130 is slower than the etching rate of the metal layer 240 with respect to the dry etching conditions described above. That is, in the above described etching process, a selection ratio between the transparent conductive layer 130 and the metal layer 240 is high. Therefore, when the metal layer 240 is etched, the surface of the transparent conductive layer 130 is exposed, at which point the etching stops or the progress of the etching becomes slow. That is, in the etching of the metal layer 240, the metal layer 240 is etched using the transparent conductive layer 130 as an etching stopper.

In other words, in the plan view, the metal layer 240 is etched such that the transparent conductive layer 130 remains on the oxide insulating layer 120 in a region where the metal layer 240 is removed. By this step, the patterned metal layer 240 can be formed without completely removing the transparent conductive layer 130.

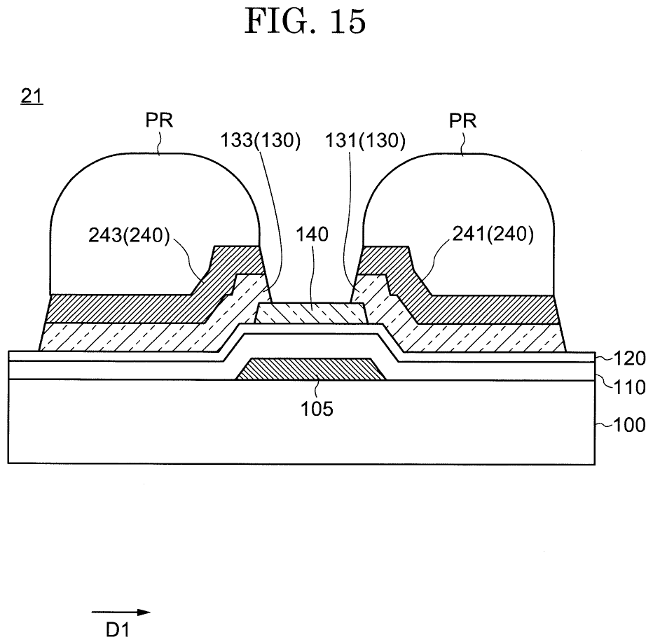

In step S1023 (transparent conductive layer etching) of FIG. 12, the transparent conductive layer 130 is etched while the resist mask PR is formed on the metallic layer 240 (see FIG. 15). The pattern of the transparent conductive layer 130 (the source electrode 131 and the drain electrode 133) is formed by the etching. Since the etching of the conductive layer in the step S1023 is performed in the same manner as the etching of the conductive layer in the step S1006 in FIG. 4, the detailed explanation thereof will be omitted.

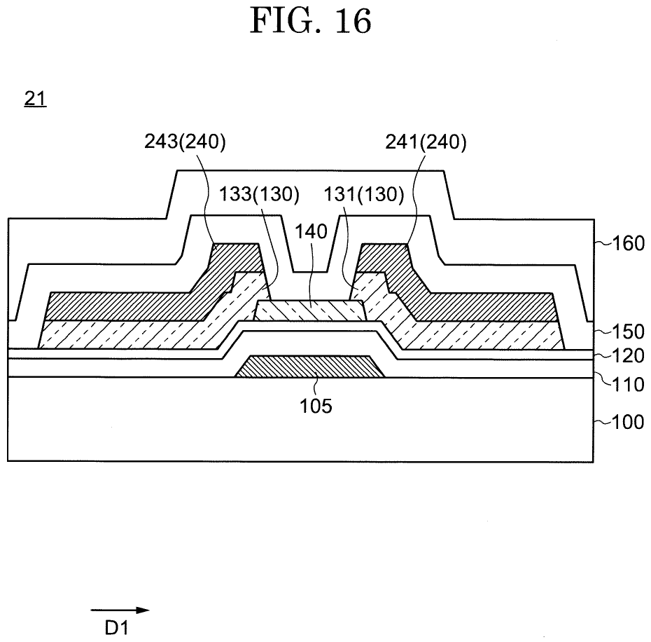

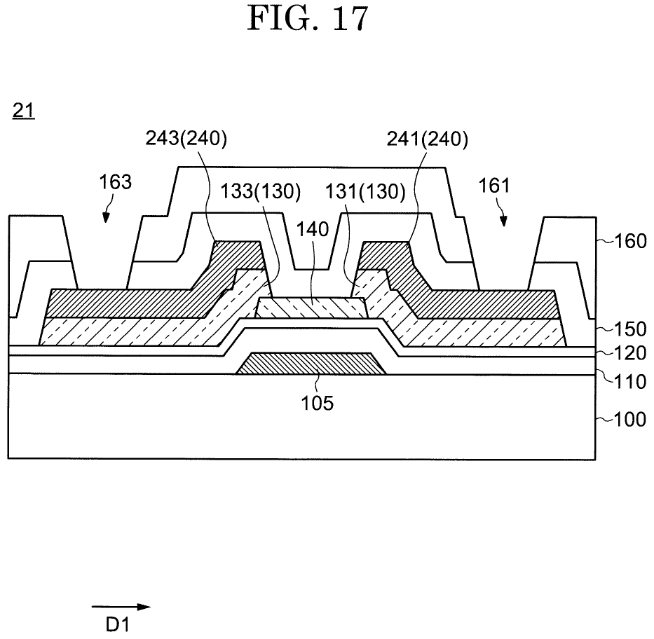

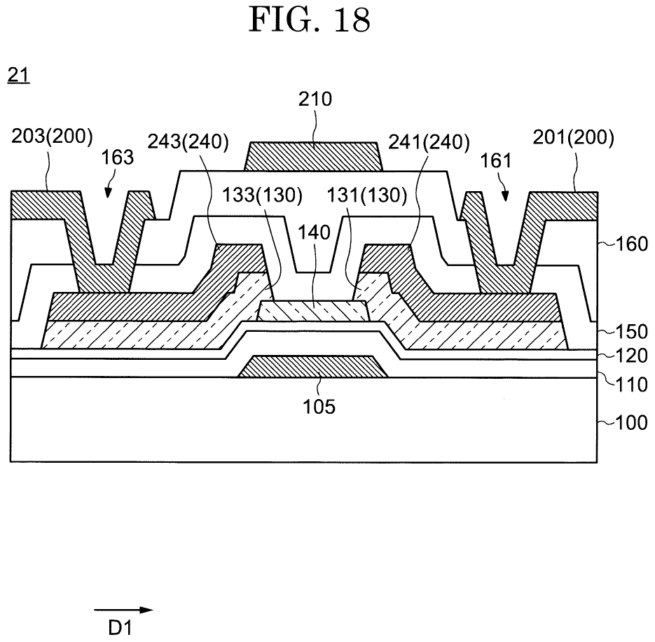

In the step S1007 (insulating layer formation) of FIG. 12, the oxide insulating layer 150 is formed on the metallic layer 240, the oxide semiconducting layer 140, and the oxide insulating layer 120 (see FIG. 16). The oxide insulating layer 150 has a thickness of 100 nm or less. The oxide insulating layer 150 is formed by the CVD (Chemical Vapor Deposition) method or a sputtering method. After the oxide insulating layer 150 is formed, oxidation annealing is performed in the same manner as in the step S1008 of FIG. 4, and the nitride insulating layer 160 is formed on the oxide insulating layer 150 in the same manner as in the step S1009 of FIG. 4 (see FIG. 16). Next, the apertures 161 and 163 are formed in the same manner as in the step S1010 of FIG. 4 (see FIG. 17). Then, the source wiring 201, the drain wiring 203, and the gate electrode 210 are formed in the same manner as in the step S1011 of FIG. 4 (see FIG. 18).

As described above, according to the semiconductor device 21 of the present embodiment, the same effects as those of the semiconductor device 20 of the first embodiment can be obtained.

### 3. Third Embodiment

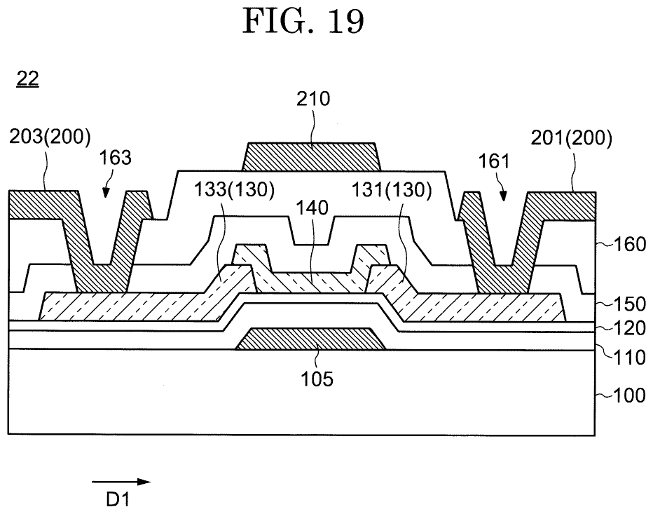

With reference to FIG. 19 to FIG. 26, the configuration of a semiconductor device 22 according to an embodiment of the present invention will be described. The semiconductor device 22 according to the present embodiment is similar to the semiconductor device 20 according to the first embodiment, but is different from the semiconductor device 20 in a positional relationship between the transparent conductive layer 130 and the oxide semiconductor layer 140.

### [3-1. Configuration of Semiconductor Device 22]

A configuration of the semiconductor device 22 used in the radiation detection device 10 according to the embodiment of the present invention will be described with reference to FIG. 19. FIG. 19 is a cross-sectional view of a semiconductor device according to an embodiment of the present invention. As shown in FIG. 19, the oxide semiconductor layer 140 is arranged on the transparent conductive layer 130. The oxide semiconductor layer 140 rides on the end portion of the source electrode 131 and the end portion of the drain electrode 133. In other words, the oxide semiconductor layer 140 is in contact with the upper surface and the side surface of the source electrode 131, and is in contact with the upper surface and the side surface of the drain electrode 133.

### [3-2. Method for Manufacturing Semiconductor Device 22]

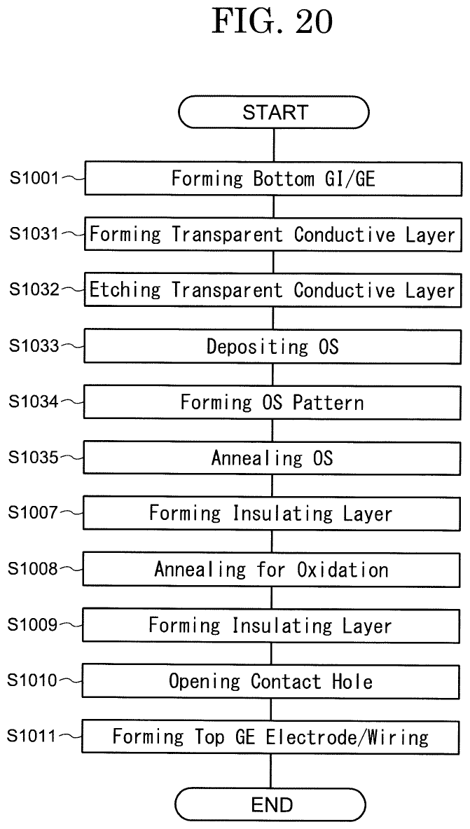

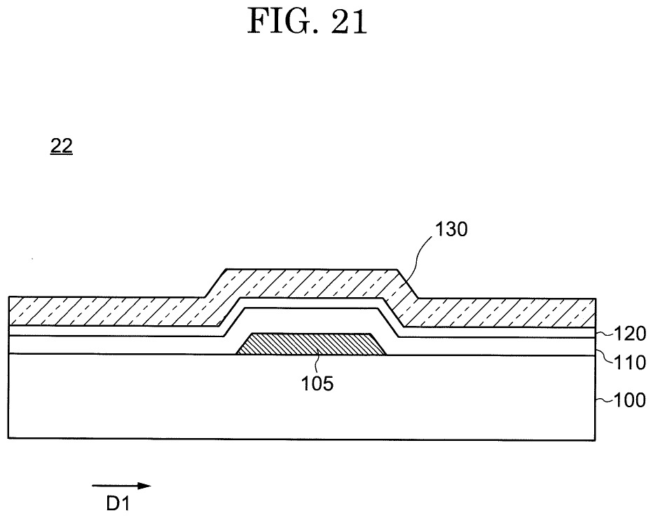

With reference to FIG. 20 to FIG. 26, a method for manufacturing the semiconductor device 22 according to an embodiment of the present invention will be described. FIG. 20 is a flowchart showing a method for manufacturing the semiconductor device 22 according to an embodiment of the present invention. FIG. 21 to FIG. 26 are schematic cross-sectional views showing a method for manufacturing the semiconductor device 22 according to an embodiment of the present invention. In the flowchart shown in FIG. 20, step S1001 is the same as the step S1001 in the flowchart shown in FIG. 4, and therefore will not be described again.

In step S1031 (transparent conductive layer formation) of FIG. 20, the transparent conductive layer 130 is formed on the oxide insulating layer 120 (see FIG. 21). The transparent conductive layer 130 is formed on the entire surface of the oxide insulating layer 120.

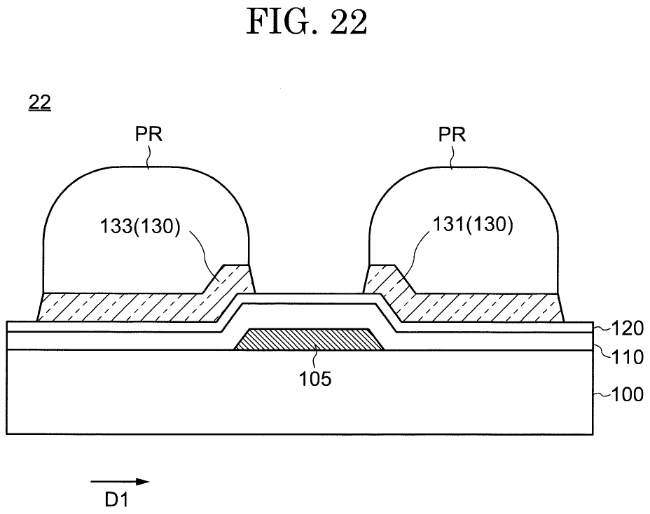

In step S1032 (transparent conductive layer etching) of FIG. 20, the resist mask PR is formed on the transparent conductive layer 130, and the transparent conductive layer 130 is etched using the resist mask PR (see FIG. 22). A pattern of the transparent conductive layer 130 (the source electrode 131 and the drain electrode 133) is formed by the etching.

Wet etching may be used, or dry etching may be used as the etching of the transparent conductive layer 130. Wet etching can be performed using an acidic etchant. For example, oxalic acid, PAN, sulfuric acid, hydrogen peroxide solution, or hydrofluoric acid can be used as the etchant. In the present embodiment, an etchant containing oxalic acid is used.

Here, the oxide insulating layer 120 has etching resistance to the etchant. In other words, with respect to the etching rate for the etchant, the etching rate of the oxide insulating layer 120 is slower than the etching rate of the transparent conductive layer 130. That is, in the above described etching process, a selection ratio between the transparent conductive layer 130 and the oxide insulating layer 120 is high. Therefore, when the transparent conductive layer 130 is etched, the surface of the oxide insulating layer 120 is exposed, at which point the etching stops or the progress of the etching becomes slow. That is, in the etching of the transparent conductive layer 130, the transparent conductive layer 130 is etched using the oxide insulating layer 120 as an etching stopper.

In other words, in the plan view, the transparent conductive layer 130 is etched so that the oxide insulating layer 120 remains on the nitride insulating layer 110 in a region where the transparent conductive layer 130 is removed. By this step, the patterned transparent conductive layer 130 can be formed without completely removing the oxide insulating layer 120. After the pattern formation of the transparent conductive layer 130 is completed, the transparent conductive layer 130 is crystallized by a heat treatment.

In step S1033 (OS film formation) of FIG. 20, the oxide semiconductive layer 140 is formed on the oxide insulating layer 120 and on the transparent conductive layer 130. The oxide semiconductor layer 140 is formed by a sputtering method or the atomic layer deposition method (ALD). The method for forming the oxide semiconductor layer 140 is the same as that of the first embodiment.

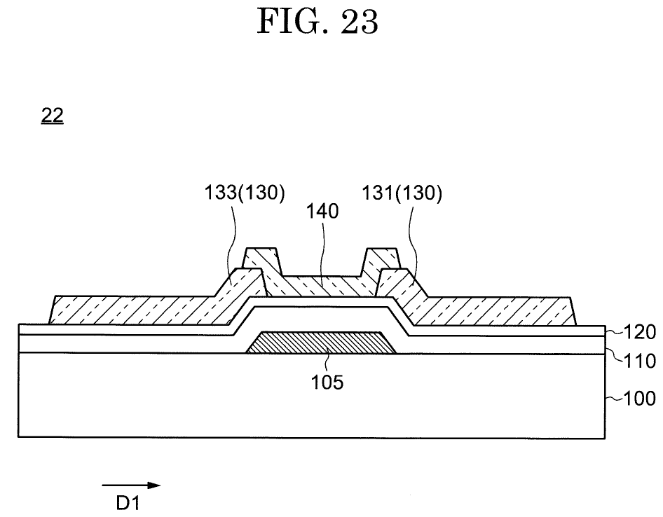

In step S1034 (OS patterning) of FIG. 20, a pattern of the oxide semiconductor layer 140 is formed (see FIG. 23). A resist mask (not shown) is formed on the oxide semiconductor layer 140, and the pattern is formed by etching the oxide semiconductor layer 140 using the resist mask. Wet etching may be used as the etching of the oxide semiconductor layer 140, or dry etching may be used. Wet etching can be performed using an acidic etchant. For example, oxalic acid, PAN, sulfuric acid, hydrogen peroxide solution, or hydrofluoric acid can be used as the etchant. Through this step, the patterned oxide semiconductor layer 140 can be formed. Thereafter, the resist mask is removed.

Here, the crystallized transparent conductive layer 130 has etching resistance to the etching conditions described above as compared with the oxide semiconductor layer 140. In other words, with respect to an etching rate for the etchant described above, an etching rate of the crystallized transparent conductive layer 130 is slower than an etching rate of the oxide semiconductor layer 140. That is, with respect to the etching, the selection ratio between the transparent conductive layer 130 and the oxide semiconductor layer 140 is high. Therefore, when the oxide semiconductor layer 140 is etched, the surface of the transparent conductive layer 130 is exposed, at which point the etching stops or the progress of the etching becomes slow. That is, in the etching of the oxide semiconductor layer 140, the oxide semiconductor layer 140 is etched using the transparent conductive layer 130 as an etching stopper.

In step S1035 (OS annealing) of FIG. 20, after the patterned oxide semiconductor layer 140 is formed, the oxide semiconductor layer 140 is subjected to a heat treatment (OS annealing). A condition of OS annealing is the same as the condition of OS annealing in the step 1004 of FIG. 4.

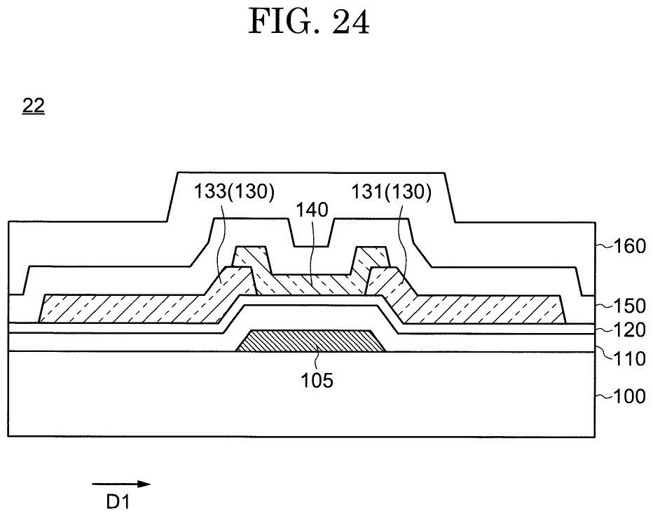

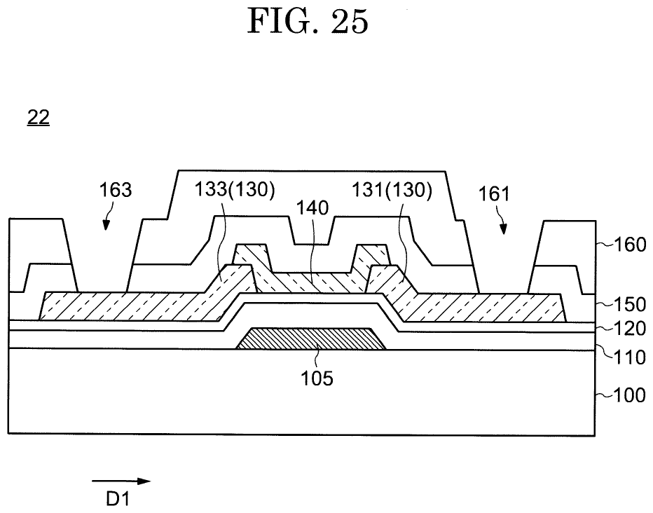

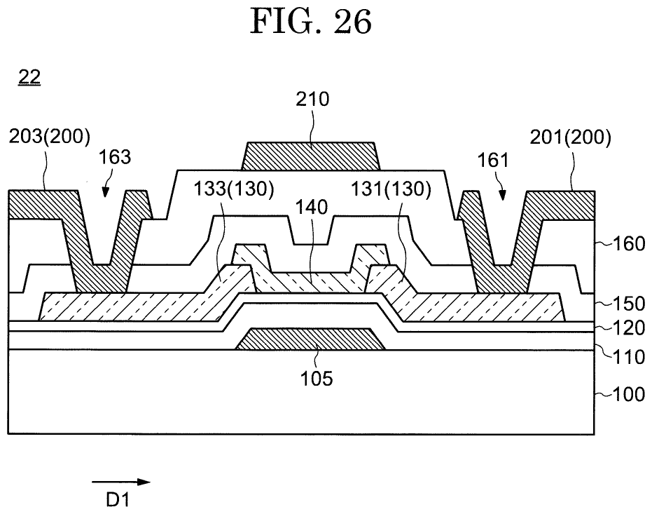

In the step S1007 (insulating layer formation) of FIG. 20, an oxide insulating layer 150 is formed on the transparent conductive layer 130, the oxide semiconductor layer 140, and the oxide insulating layer 120 (see FIG. 24). The oxide insulating layer 150 has a thickness of 100 nm or less. The oxide insulating layer 150 is formed by the CVD (Chemical Vapor Deposition) method or a sputtering method. After the oxide insulating layer 150 is formed, oxidation annealing is performed in the same manner as in the step S1008 of FIG. 4, and the nitride insulating layer 160 is formed on the oxide insulating layer 150 in the same manner as in the step S1009 of FIG. 4 (see FIG. 24). Next, the apertures 161 and 163 are formed in the same manner as in the step S1010 of FIG. 4 (see FIG. 25). Then, the source wiring 201, the drain wiring 203, and the gate electrode 210 are formed in the same manner as in the step S1011 of FIG. 4 (see FIG. 26).

As described above, according to the semiconductor device 22 of the present embodiment, the same effects as those of the semiconductor device 20 of the first embodiment can be obtained.

Each of the embodiments described above as the embodiment of the present invention can be appropriately combined as long as they are not mutually contradictory. Further, based on the semiconductor device and the radiation detector of each embodiment, additions, deletions, or design changes of the components, or those additions, deletions, or condition changes of the steps made by a person skilled in the art as appropriate are also included in a scope of the present invention as long as it comprises the gist of the present invention.

It is to be understood that the present invention provides other operational effects that are different from operational effects provided by aspects of the embodiments described above, and those that are obvious from descriptions of the present specification or those that can be easily predicted by a person skilled in the art.

What is claimed is:

1. A method for manufacturing a semiconductor device for a radiation detection device comprising:
forming a first gate electrode above an insulating surface;
forming a first nitride insulating layer above the first gate electrode;
forming a first oxide insulating layer above the first nitride insulating layer, a thickness of the first oxide insulating layer being 20 nm or less;
forming an oxide semiconductor layer above the first oxide insulating layer;
forming a transparent conductive layer above the oxide semiconductor layer; and
forming a source electrode and a drain electrode by etching the transparent conductive layer using the first oxide insulating layer and the oxide semiconductor layer as etching stoppers.

2. The method according to claim 1, wherein the etching of the transparent conductive layer is a wet etching.

3. The method according to claim 2, wherein the wet etching uses an etchant including an oxalic acid.

4. The method according to claim 1, further comprising:
forming a second oxide insulating layer above the oxide semiconductor layer, the source electrode, and the drain electrode, a thickness of the second oxide insulating layer being 100 nm or less;
forming a second nitride insulating layer above the second oxide insulating layer;
forming apertures reaching the source electrode and the drain electrode in the second oxide insulating layer and the second nitride insulating layer; and
forming a wiring above the second nitride insulating layer and inside the aperture, the wiring being in contact with the source electrode and the drain electrode in a bottom part of the aperture.

5. The method according to claim 4, further comprising forming a second gate electrode above the second nitride insulating layer together with the wiring, the second gate electrode overlapping the oxide insulating layer between the source electrode and the drain electrode in a plan view.

6. The method according to claim 1, wherein
the source electrode and the drain electrode are formed by:
forming the transparent conductive layer above the first oxide insulating layer;
forming a metal layer above the transparent conductive layer;
etching the metal layer using the transparent conductive layer as an etching stopper; and
etching the transparent conductive layer exposed from the metal layer using the first oxide insulating layer and the oxide insulating layer as etching stoppers.

7. The method according to claim 1, further comprising:
forming a photoelectric transfer layer above the semiconductor device and connected to the semiconductor device; and
forming a wavelength conversion layer facing the photoelectric transfer layer, the wavelength conversion layer absorbing radiation and emitting visible light based on the absorbed radiation.

8. A method for manufacturing a semiconductor device comprising:
forming a first gate electrode above an insulating surface;
forming a first nitride insulating layer above the first gate electrode;
forming a first oxide insulating layer above the first nitride insulating layer, a thickness of the first oxide insulating layer being 20 nm or less;
forming an oxide semiconductor layer above the first oxide insulating layer;
forming a transparent conductive layer above the first oxide insulating layer and the oxide semiconductor layer; and
forming a source electrode and a drain electrode by etching the transparent conductive layer so that the oxide semiconductor layer remains above the first oxide insulating layer in a channel region and so that the first oxide insulating layer remains above the first nitride insulating layer in a region in which the transparent conductive layer is removed other than the channel region in a plan view.

9. The method according to claim 8, wherein the transparent conductive layer is etched by wet etching.

10. The method according to claim 9, wherein the wet etching process uses an etchant including an oxalic acid.

11. The method according to claim 8, further comprising:
forming a second oxide insulating layer above the oxide semiconductor layer, the source electrode and the drain electrode, a thickness of the second oxide insulating layer being 100 nm or less;
forming a second nitride insulating layer above the second oxide insulating layer;
forming apertures reaching the source electrode and the drain electrode in the second oxide insulating layer and the second nitride insulating layer; and
forming a wiring above the second nitride insulating layer and inside the aperture, the wiring being in contact with the source electrode and the drain electrode in a bottom part of the aperture.

12. The method according to claim 11, further comprising forming a second gate electrode above the second nitride insulating layer together with the wiring, the second gate electrode overlapping the oxide insulating layer between the source electrode and the drain electrode in a plan view.

13. The method according to claim 8, wherein
the source electrode and the drain electrode are formed by:
forming the transparent conductive layer above the first oxide insulating layer;
forming a metal layer above the transparent conductive layer;
etching the metal layer using the transparent conductive layer as an etching stopper; and
etching the transparent conductive layer exposed from the metal layer using the first oxide insulating layer and the oxide insulating layer as etching stoppers.

14. The method according to claim 8, wherein
the source electrode and the drain electrode are formed by:
forming the transparent conductive layer above the first oxide insulating layer and the oxide semiconductor layer;
forming a metal layer above the transparent conductive layer;
etching the metal layer so that the transparent conductive layer remains above the oxide semiconductor layer in the channel region and so that the oxide semiconductor layer remains above the first oxide insulating layer in a region in which the transparent conductive layer is removed other than the channel region in a plan view; and
etching the transparent conductive layer so that the oxide semiconductor layer remains above the first oxide insulating layer in the channel region and so that the first oxide insulating layer remains above the first nitride insulating layer in a region in which the transparent conductive layer is removed other than the channel region in a plan view.

15. The method according to claim 8, further comprising:
forming a photoelectric transfer layer above the semiconductor device and connected to the semiconductor device; and
forming a wavelength conversion layer facing the photoelectric transfer layer, the wavelength conversion layer absorbing radiation and emitting a visible light based on the absorbed radiation.
